(19) United States
(12) Patent Application Publication
(10) Pub. No.: US 2013/0015570 A1
(43) Pub. Date: Jan. 17, 2013

(54) STACKED SEMICONDUCTOR PACKAGE AND MANUFACTURING METHOD THEREOF

(71) Applicant: Takao Sato, Edogawa-ku (JP)

(72) Inventor: Takao Sato, Edogawa-ku (JP)

(73) Assignee: Kabushiki Kaisha Toshiba, Tokyo (JP)

(21) Appl. No.: 13/411,061

(22) Filed: Mar. 2, 2012

(30) Foreign Application Priority Data
Jul. 13, 2011 (JP) 2011-154768

(51) Int. Cl. H01L 23/538; H01L 21/50; H01L 23/498

(52) U.S. Cl. 257/737; 257/777; 438/107; 257/E23.169; 257/E23.068; 257/E21.499

(57) ABSTRACT

In an embodiment, a stacked semiconductor package includes a wiring board having external connection terminals and internal connection terminals, and first and second modules stacked on the wiring board. Each of the first and second modules includes a plurality of semiconductor chips mounted on an interposer and a sealing resin layer. The interposers and the internal connection terminals of the wiring board are electrically connected by connecting members such as metal wires, printed wiring layers or metal bumps. The first and second modules are collectively sealed by a sealing resin layer formed on the wiring board.

### CROSS-REFERENCE TO RELATED APPLICATION

This application is based upon and claims the benefit of priority from Japanese Patent Application No. 2011-154768, filed on Jul. 13, 2011; the entire contents of which are incorporated herein by reference.

### FIELD

Embodiments described herein relate generally to a stacked semiconductor package and a manufacturing method thereof.

### BACKGROUND

In a semiconductor memory device having a memory chip such as a NAND-type flash memory built therein, there has been applied a structure in which thickness-reduced memory chips are stacked in multiple tiers to be mounted on a wiring board, in order to realize miniaturization and high capacitance. According to a thickness-reduction technique for semiconductor chips, the number of stacked semiconductor chips such as memory chips is apt to increase. Further, as a stacking structure of semiconductor chips such as memory chips, a structure in which previously packaged semiconductor chips are stacked in multiple tiers, which is, so-called POP (Package on Package) structure, has been known.

In a semiconductor package in which semiconductor chips are stacked in multiple tiers and sealed, an assembly yield and an inspection yield are likely to decrease as the number of stacked semiconductor chips increases. An inspection of electric characteristics of semiconductor chips is generally conducted also after assembling the semiconductor package, so that due to initial failure or problem of one semiconductor chip, the entire semiconductor package is regarded as a defect. The defect as the semiconductor package is likely to occur as the number of stacked semiconductor chips increases. In the POP structure, semiconductor chips which are previously judged as non-defective are assembled, so that a high yield can be expected, but a thickness as an entire package (POP) is likely to increase.

### BRIEF DESCRIPTION OF THE DRAWINGS

FIG. 1 is a sectional view showing a stacked semiconductor package according to a first embodiment.

FIG. 2 is a view showing a relation between a ratio of a resin thickness of the stacked semiconductor package to a resin thickness of first and second modules and a warpage of the stacked semiconductor package.

FIG. 3 is a view showing a relation between an elasticity modulus of a sealing resin layer and a warpage of the stacked semiconductor package.

FIG. 4 is a sectional view showing a stacked semiconductor package according to a second embodiment.

FIG. 5 is a sectional view showing a stacked semiconductor package according to a third embodiment.

FIG. 6 is a sectional view showing a stacked semiconductor package according to a fourth embodiment.

### DETAILED DESCRIPTION

According to one embodiment, there is provided a stacked semiconductor package including a wiring board having a first surface including external connection terminals and a second surface including internal connection terminals, a first module disposed on the second surface of the wiring board, and a second module stacked on the first module. The first module includes a first interposer, a plurality of first semiconductor chips mounted on the first interposer, first connecting members electrically connecting the first interposer and the first semiconductor chips, and a first sealing resin layer formed on the first interposer to seal the first semiconductor chips together with the first connecting members. The second module includes a second interposer, a plurality of second semiconductor chips mounted on the second interposer, second connecting members electrically connecting the second interposer and the second semiconductor chips, and a second sealing resin layer formed on the second interposer to seal the second semiconductor chips together with the second connecting members. The first interposer and the internal connection terminals of the wiring board are electrically connected via third connecting members. The second interposer and the internal connection terminals of the wiring board are electrically connected via fourth connecting members.

### First Embodiment

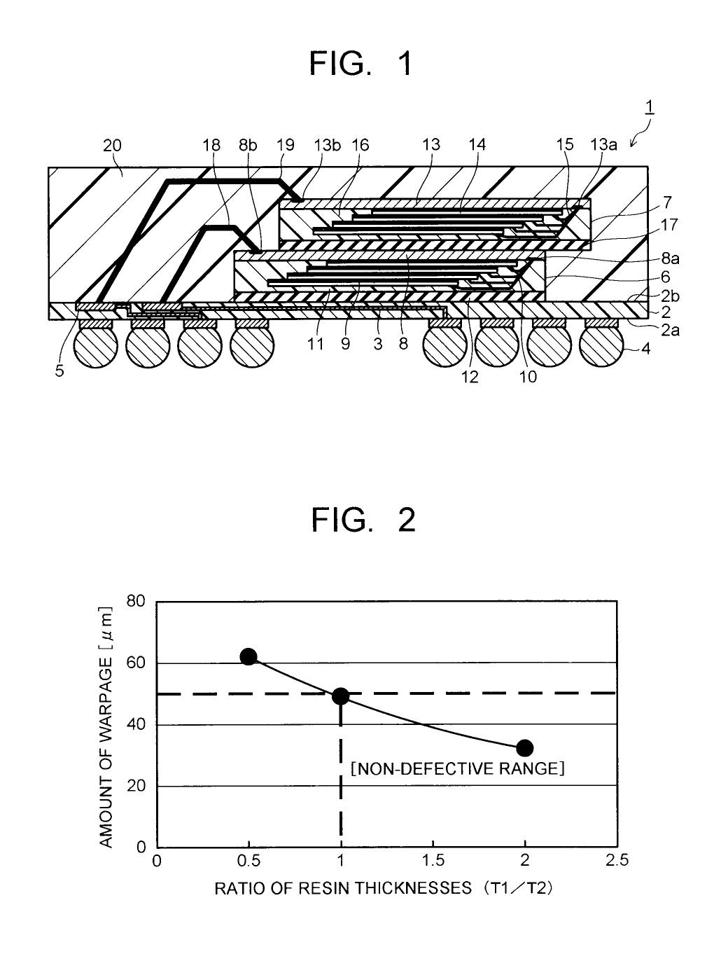

FIG. 1 is a sectional view showing a configuration of a stacked semiconductor package of a first embodiment. A stacked semiconductor package 1 includes a wiring board 2. The wiring board 2 is formed by providing a wiring network 3 on a surface or inside of an insulating resin substrate. As the wiring board 2, a printed wiring board (multilayer printed board) or the like using an insulating resin such as a glass-epoxy resin and a BT resin (Bismaleimide-Triazine resin) is applied. The wiring board 2 has a first surface 2a to be a forming surface of external connection terminals and a second surface 2b to be amounting surface of module having semiconductor chips.

On the first surface 2a of the wiring board 2, external connection terminals 4 are formed. When a BGA package is configured by the stacked semiconductor package 1, the external connection terminals 4 are formed of projecting terminals made of solder ball, solder plating, Au plating or the like. When an LGA package is configured by the stacked semiconductor package 1, metal lands are provided as the external connection terminals 4. On the second surface 2b of the wiring board 2, internal connection terminals 5 are provided. The internal connection terminals 5 function as connection portions (connection pads) at a time of connecting the wiring board 2 and a module including semiconductor chips, and are electrically connected to the external connection terminals 4 via the wiring network 3 of the wiring board 2.

On the second surface 2b of the wiring board 2, a first module 6 is disposed. Further, on the first module 6, a second module 7 is stacked. The first module 6 includes a first interposer 8, a plurality of first semiconductor chips 9 mounted on the first interposer 8, first connecting members 10 electrically connecting the first interposer 8 and the first semiconductor chips 9, and a first sealing resin layer 11 formed on the first interposer 8 to seal the first semiconductor chips 9 together with the first connecting members 10.

As the first interposer 8, a silicon interposer or an interposer board is used, for example. The silicon interposer is formed by providing a wiring network inside or on a surface of a silicon substrate. The interposer board is formed by providing a wiring network on a surface or inside of an insulating resin substrate, similar to the wiring board 2. The first interposer 8 may also be a multiple wiring layer formed by utilizing a supporting substrate. On a first surface of the first interposer 8, connection terminals (internal terminals) 8a are provided. On a second surface opposed to the first surface of the first interposer 8, connection terminals (external terminals) 8b are provided. The connection terminals 8b are electrically connected to the connection terminals 8a via a wiring network of the first interposer 8 whose illustration is omitted.

On the first surface of the first interposer 8, a plurality of first semiconductor chips 9 are stacked in a stepped manner. The first semiconductor chips 9 respectively have electrode pads (not-shown) arranged along outer edges, and are stacked in the stepped manner to expose these electrode pads. As a concrete example of the first semiconductor chip 9, a memory chip such as a NAND-type flash memory can be cited, but it is not limited to this. The electrode pads of the first semiconductor chips 9 and the connection terminals 8a of the first interposer 8 are electrically connected via metal wires as the first connecting members 10.

As the first connecting members 10, it is also possible to apply printed wiring layers, instead of the metal wires. As shown in later-described another embodiment, it is also possible to apply through electrodes or a combination of the through electrodes and metal wires, as the first connecting members 10. The printed wiring layer is formed by an application of conductive paste in accordance with a desired wiring pattern, by using an ink-jet method or a screen printing method. On the first surface of the first interposer 8, the first sealing resin layer 11 made of an insulating resin such as an epoxy resin is formed by molding so as to seal the first semiconductor chips 9 together with the first connecting members 10.

The first sealing resin layer 11 of the first module 6 is adhered to the second surface 2b of the wiring board 2 via a first adhesive layer 12. As the first adhesive layer 12, an adhesive film, an adhesive paste or the like is used. The first module 6 is disposed so that the first interposer 8 is at an upper position, and the first sealing resin layer 11 is at a lower position. The upper position and the lower position mentioned here correspond to a positional relationship on a mounting board at a time of mounting the stacked semiconductor package 1 on the mounting board. In the first module 6 shown in FIG. 1, the first sealing resin layer 11 disposed on the wiring board 2 side is adhered to the wiring board 2 via the first adhesive layer 12. The first module 6 is disposed so that the second surface of the first interposer 8 faces upward, and the connection terminal 8b provided on the second surface is exposed upward.

The second module 7 includes, similar to the first module 6, a second interposer 13, a plurality of second semiconductor chips 14 mounted on the second interposer 13, second connecting members 15 electrically connecting the second interposer 13 and the second semiconductor chips 14, and a second sealing resin layer 16 formed on the second interposer 13 so as to seal the second semiconductor chips 14 together with the second connecting members 15. The configuration and the state of disposition of the second interposer 13, the second semiconductor chips 14, the second connecting members 15 and the second sealing resin layer 16 in the second module 7 are similar to those of the first module 6.

On a first surface of the second interposer 13, connection terminals (internal terminals) 13a are provided. On a second surface opposed to the first surface of the second interposer 13, connection terminals (external terminals) 13b is provided. On the first surface of the second interposer 13, the plurality of second semiconductor chips 14 are stacked in a stepped manner, so as to expose electrode pads (not shown). The electrode pads of the second semiconductor chips 14 and the connection terminals 13a of the second interposer 13 are electrically connected via metal wires as the second connecting members 15. The second connecting members 15 may also be printed wiring layers, through electrodes or the like.

On the first surface of the second interposer 13, the second sealing resin layer 16 made of an insulating resin such as an epoxy resin is formed by molding so as to seal the second semiconductor chips 14 together with the second connecting members 15. Similar to the first module 6, the second module 7 is disposed so that the second interposer 13 is at an upper position, and the second sealing resin layer 16 is at a lower position. In the second module 7 shown in FIG. 1, the second sealing resin layer 16 disposed on the first module 6 side is adhered to the second surface of the first interposer 8 via a second adhesive layer 17. The second module 7 is disposed so that the second surface of the second interposer 13 faces upward, and the connection terminals 13b provided on the second surface are exposed upward.

The connection terminals 8b provided on the second surface of the first interposer 8 are electrically connected to the internal connection terminals 5 of the wiring board 2 via third connecting members 18. The connection terminals 13b provided on the second surface of the second interposer 13 are electrically connected to the internal connection terminals 5 of the wiring board 2 via fourth connecting members 19. As the third and fourth connecting members 18 and 19, metal wires are used, for example. As the connecting members 18, 19, it is also possible to apply printed wiring layers, instead of the metal wires. The second module 7 is disposed on the first module 6 while being deviated from the first module 6, so that the connection terminals 8b of the first interposer 8 are exposed.

On the second surface 2b of the wiring board 2, a third sealing resin layer 20 made of an insulating resin such as an epoxy resin is formed by molding so as to seal the first and second modules 6 and 7 together with the third and fourth connecting members 18 and 19. As above, the first module 6 configured by mounting the plurality of first semiconductor chips 9 on the first interposer 8 and the second module 7 configured by mounting the plurality of second semiconductor chips 14 on the second interposer 13 are stacked on the wiring board 2, and collectively sealed by the third sealing resin layer 20, thereby configuring the stacked semiconductor package 1 of the first embodiment.

It is preferable that the numbers of mounted semiconductor chips 9, 14 on the interposers 8, 13 in the first and second modules 6 and 7 are respectively set to 4 to 8. If the numbers of mounted semiconductor chips 9, 14 are set as above, it is possible to improve an assembly yield and an inspection yield of the semiconductor chips 9, 14. Further, by previously inspecting electric characteristics at the stage where the modules 6, 7 are manufactured, and mounting only the modules 6, 7 whose electric characteristics are judged as acceptable on the wiring board 2, it becomes possible to improve a manufacturing yield of the stacked semiconductor package 1. Further, since the plurality of semiconductor chips 9, 14 are stacked in the respective modules 6, 7, it is possible to reduce a thickness of the stacked semiconductor package 1, compared to a case where the semiconductor chips which are independently packaged are stacked.

In the stacked semiconductor package 1 of the first embodiment, the respective modules 6, 7 are disposed on the wiring board 2 so that the interposers 8, 13 are at upper positions, so that the connection terminals 8b, 13b provided on the second surfaces of the respective interposers 8, 13 can be used for connecting the modules 6, 7 and the internal connection terminals 5 of the wiring board 2. Therefore, it is possible to electrically connect the respective modules 6, 7 and the wiring board 2 by utilizing normal wire bonding or printed wirings, without applying complicated shapes for the connection terminals or a special wiring structure for connecting the interposers and the wiring board. Accordingly, it is possible to suppress an increase in manufacturing cost of the stacked semiconductor package 1. It becomes possible to provide a thin stacked semiconductor package 1 that deals with an increase in the semiconductor chips 9, 14, at a low cost with good yield.

The stacked semiconductor package 1 has a structure in which the resin-sealed modules 6, 7 are further resin-sealed by the third sealing resin layer 20. Specifically, the stacked semiconductor package 1 has a mold-in-mold structure. For this reason, there is a possibility that the warpage of the stacked semiconductor package 1 becomes likely to occur. It is conceivable that a ratio of resin thicknesses and a ratio of elasticity moduli between the first and second sealing resin layers 11, 16 and the third sealing resin layer 20 exert an influence on the warpage of the stacked semiconductor package 1. In the stacked semiconductor package 1 with the mold-in-mold structure, since the sealing resin exists on both upper and lower surfaces of the interposers 8, 13 and the semiconductor chips 9, 14, it is conceivable that the warpage becomes likely to occur depending on the ratio of resin thicknesses and the ratio of elasticity moduli.

In the stacked semiconductor package 1, it is preferable that a thickness of the third sealing resin layer 20 on the second module 7 (resin thickness T1) with respect to a thickness of the first sealing resin layer 11 on the first semiconductor chip 9 (resin thickness T2) and a thickness of the second sealing resin layer 16 on the second semiconductor chip 14 (resin thickness T2) satisfies a condition of T1≧T2. When such a condition is satisfied, a balance between the resin thickness T1 of the third sealing resin layer 20 and the resin thickness T2 of the sealing resin layers 11, 16 in the modules 6, 7 becomes good, and the warpage of the stacked semiconductor package 1 can be suppressed.

FIG. 2 shows a relation between the ratio of the resin thickness T1 of the third sealing resin layer 20 to the resin thickness T2 of the sealing resin layers 11, 16 in the modules 6, 7 (T1/T2) and an amount of warpage of the stacked semiconductor package 1. When the amount of warpage of the stacked semiconductor package 1 is 50 μm or less, the package can be judged as non-defective. As is apparent from FIG. 2, by setting the T1/T2 ratio to 1 or more (T1≧T2), it is possible to suppress the warpage of the stacked semiconductor package 1. The T1/T2 ratio is preferably set to fall within a range of 1 to 2, and is more preferably set to fall within a range of 1 to 1.5.

The resin thicknesses T1, T2 of the sealing resin layers 11, 16, 20 are set in accordance with a diameter of filler included in the sealing resin (molding resin), a height of wire in a case of applying wire bonding, and the like. It is preferable that a concrete value of each of the resin thicknesses T1, T2 is set to fall within a range of 70 to 200 μm. It is preferable that the resin thicknesses T1, T2 of the sealing resin layers 11, 16, 20 are set to satisfy the range as above, and then the T1/T2 ratio is set to fall within the range of 1 to 2, more preferably, within the range of 1 to 1.5. For example, when the resin thickness T2 of the sealing resin layers 11, 16 is set to approximately 100 μm, by setting the T1/T2 ratio to fall within the range of 1 to 1.5, it is possible to suppress the warpage of the stacked semiconductor package 1 without increasing the thickness of the stacked semiconductor package 1 too much.

In the stacked semiconductor package 1, an elasticity modulus E1 of the third sealing resin layer 20 with respect to an elasticity modulus E2 of the first and second sealing resin layers 11 and 16 is preferably set to satisfy a condition of E1≧E2. Accordingly, the warpage of the stacked semiconductor package 1 due to the first and second modules 6 and 7 can be suppressed by the third sealing resin layer 20. Specifically, by the third sealing resin layer 20 with the elasticity modulus equal to or higher than that of the first and second sealing resin layers 11 and 16, the warpage of the stacked semiconductor package 1 based on the structure of mounting the first and second modules 6 and 7 on the wiring board 2 can be suppressed by the third sealing resin layer 20. Therefore, it becomes possible to suppress the warpage of the stacked semiconductor package 1.

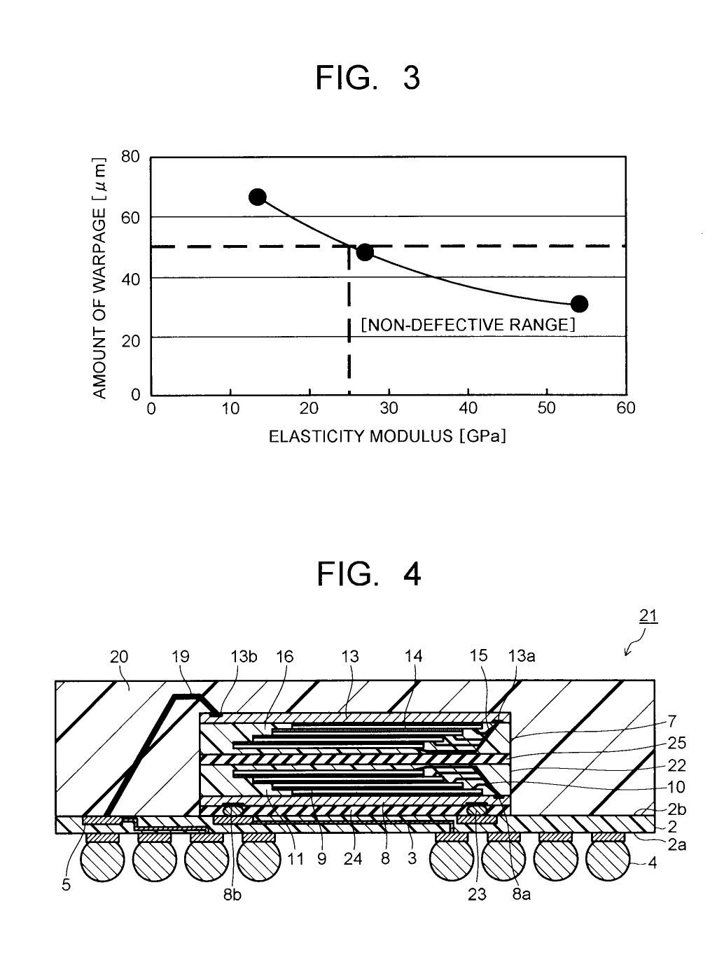

FIG. 3 shows an amount of warpage of the stacked semiconductor package 1 at a time of changing the elasticity modulus E1 of the third sealing resin layer 20, when the elasticity modulus E2 of the first and second sealing resin layers 11 and 16 is set to 25 GPa. As is apparent from FIG. 3, by setting the E1/E2 ratio to 1 or more (E1≧E2), the warpage of the stacked semiconductor package 1 is suppressed. The elasticity moduli E1, E2 of the sealing resin layers 11, 16, 20 are elasticity moduli at room temperature. When a holding property with respect to the semiconductor chips 9, 14 or the like is taken into consideration, the elasticity modulus E2 of the first and second sealing resin layers 11 and 16 is preferably set to 22 GPa or more, and is more preferably set to 25 GPa or more. In addition to that, in order to satisfy the condition of E1≧E2, the elasticity modulus E1 of the third sealing resin layer 20 is preferably set to fall within a range of 25 to 30 GPa, and is more preferably set to fall within a range of 25 to 28 GPa.

The elasticity moduli E1, E2 of the sealing resin layers 11, 16, 20 can be adjusted by a type of filler added to a resin composition that forms the sealing resin, an amount of filling the filler, and the like. However, when the elasticity moduli of the sealing resins are too high when forming the sealing resin layers 11, 16, 20 by molding, the moldability is lowered, so that the elasticity moduli E1, E2 of the sealing resin layers 11, 16, 20 are preferably set to 30 GPa or less. The first and second sealing resin layers 11 and 16 and the third sealing resin layer 20 are preferably formed of insulating resins of the same type, but do not necessarily have to be formed in that manner. When using insulating resins of different types, it is preferable to apply a method of increasing an adhesiveness between the resins (for example, a plasma cleaning or the like for improving an adhesiveness of a contact surface).

### Second Embodiment

A stacked semiconductor package according to a second embodiment will be described with reference to FIG. 4. A stacked semiconductor package 21 shown in FIG. 4 includes a first module 22 applying flip-chip connection (FC connection) for connecting the module and the wiring board 2, instead of the first module 6 in the first embodiment, namely, the module 6 electrically connected to the wiring board 2 by the wire bonding. The stacked semiconductor package 21 of the second embodiment includes the same configuration as that of the stacked semiconductor package 1 according to the first embodiment, except for the configuration and the connection system of the first module 22.

The first module 22 in the stacked semiconductor package 21 of the second embodiment includes a first interposer 8, a plurality of first semiconductor chips 9 mounted on the first interposer 8, first connecting members 10 electrically connecting the first interposer 8 and the first semiconductor chips 9, and a first sealing resin layer 11 formed on the first interposer 8 so as to seal the first semiconductor chips 9 together with the first connecting members 10. On a first surface of the first interposer 8, connection terminals (internal terminals) 8a are provided. On a second surface opposed to the first surface of the first interposer 8, connection terminals (external terminals) 8b are provided.

The configuration so far is similar to that of the first module 6 according to the first embodiment, and it is preferable that the concrete configuration of the interposer 8 and the first connecting members 10 is also set to be similar to that of the first embodiment. The first module 22 is disposed so that the first interposer 8 is at a lower position, and the first sealing resin layer 11 is at an upper position. On the second surface of the first interposer 8, metal bumps 23 for FC connection are provided. The metal bump 23 is formed of solder ball, solder plating, metal plating such as Au plating or the like.

The metal bumps 23 are provided on the connection terminals 8b of the first interposer 8. The metal bumps 23 are electrically connected to the first semiconductor chips 9 via the first interposer 8 and metal wires or printed wiring layers as the first connecting members 10. The metal bumps 23 are FC-connected to the internal connection terminals 5 of the wiring board 2. The first module 22 is electrically and mechanically connected to the internal connection terminals 5 of the wiring board 2 via the metal bumps 23 provided on the second surface of the first interposer 8. An underfill resin 24 is filled between the first interposer 8 of the first module 22 and the wiring board 2.

Similar to the first embodiment, the second module 7 is disposed so that the second interposer 13 is at an upper position, and the second sealing resin layer 16 is at a lower position. The second sealing resin layer 16 of the second module 7 is adhered to the first sealing resin layer 11 of the first module 22 via an adhesive layer 25. Similar to the first embodiment, the second module 7 is disposed so that the second surface of the second interposer 13 faces upward, and the connection terminals 13b provided on the second surface are exposed upward. The connection terminals 13b are electrically connected to the internal connection terminals 5 of the wiring board 2 via metal wires or printed wiring layers as the fourth connecting members 19. The second module 7 is disposed immediately on the first module 6.

On the second surface 2b of the wiring board 2, the third sealing resin layer 20 made of an insulating resin such as an epoxy resin is formed by molding so as to seal the first and second modules 22 and 7 together with the connecting member 19. As above, the first module 22 configured by mounting the plurality of first semiconductor chips 9 on the first interposer 8 and the second module 7 configured by mounting the plurality of second semiconductor chips 14 on the second interposer 13 are stacked on the wiring board 2 having the external connection terminals 4, and the first module 22 is FC-connected to the wiring board 2, thereby configuring the stacked semiconductor package 21 of the second embodiment.

It is preferable that in the first and second modules 22 and 7 in the second embodiment, the numbers of mounted semiconductor chips 9, 14 on the interposers 8, 13 are respectively set to 4 to 8, similar to the first embodiment. Similar to the first embodiment, by mounting only the modules 22, 7 whose electric characteristics are judged as acceptable on the wiring board 2, it is possible to improve a manufacturing yield of the stacked semiconductor package 21. Further, it is possible to reduce a thickness of the stacked semiconductor package 21. In addition, since the respective modules 22, 7 and the wiring board 2 can be electrically connected by utilizing normal FC connection, wire bonding and the like, it is possible to suppress an increase in manufacturing cost and the like of the stacked semiconductor package 21.

Also in the stacked semiconductor package 21 according to the second embodiment, it is preferable to set the ratio of the resin thickness T1 of the third sealing resin layer 20 to the resin thickness T2 of the sealing resin layers 11, 16 in the modules 22,7 (T1/T2) to 1 or more (T1≧T2), similar to the first embodiment. The ratio of the elasticity modulus E1 of the third sealing resin layer 20 to the elasticity modulus E2 of the sealing resin layers 11, 16 (E1/E2) is preferably set to 1 or more (E1≧E2). Concrete values of the resin thicknesses T1, T2 and the elasticity moduli E1, E2 are also preferably set in a similar manner to the first embodiment. According to these structures, it is possible to suppress a warpage of the stacked semiconductor package 21.

### Third Embodiment

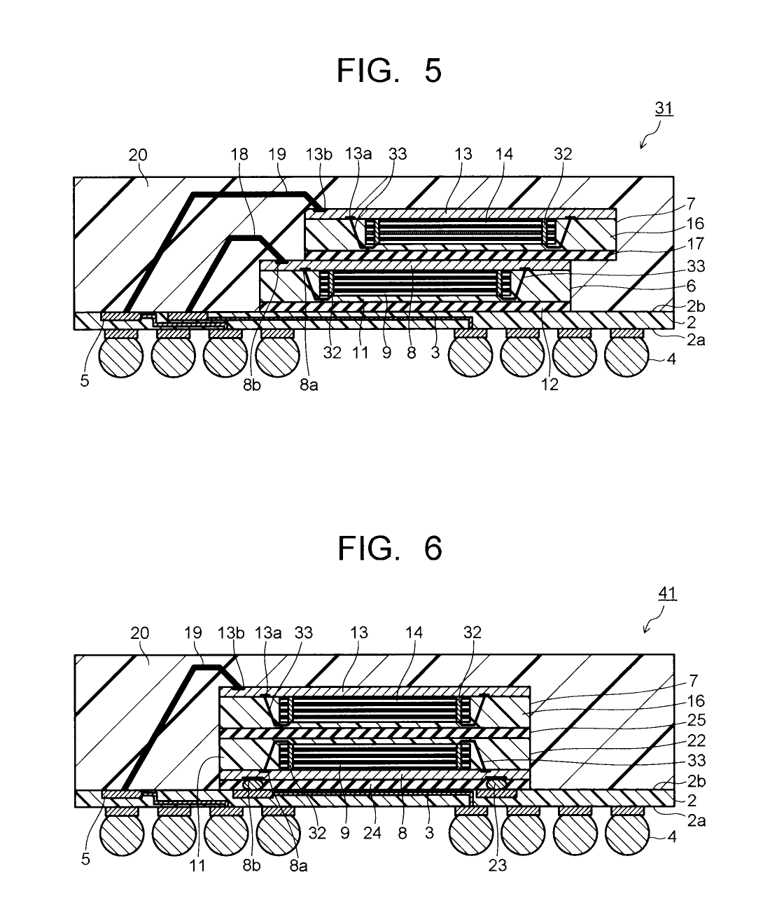

A stacked semiconductor package according to a third embodiment will be described with reference to FIG. 5. A stacked semiconductor package 31 shown in FIG. 5 includes the same configuration as that of the stacked semiconductor package 1 according to the first embodiment, except that through electrodes 32 are used to connect between the semiconductor chips 9 and between the semiconductor chips 14 in the first and second modules 6 and 7, and the semiconductor chips 9, 14 of the uppermost tiers and the interposers 8, 13 are electrically connected by metal wires 33. It is also possible to use a printed wiring layer as a substitute for the metal wire 33. The semiconductor chip 9 of the uppermost tier is based on a stacking order at the time of mounting the semiconductor chips 9 on the interposer 8, and indicates the semiconductor chip 9 disposed at a position furthermost from the interposer 8. The same applies to the semiconductor chip 14 of the uppermost tier.

The through electrodes 32 are used to electrically connect between the first semiconductor chips 9 stacked on the first surface of the first interposer 8. The uppermost semiconductor chip 9 in the semiconductor chips 9 is electrically connected to the connection terminals 8a of the first interposer 8 via the metal wires 33. The first semiconductor chips 9 are electrically connected to the first interposer 8 via the through electrodes 32 and the metal wires 33. Similarly, the through electrodes 32 are used to electrically connect between the second semiconductor chips 14 stacked on the first surface of the second interposer 13. The uppermost semiconductor chip 14 in the second semiconductor chips 14 is electrically connected to the connection terminals 13a of the second interposer 13 via the metal wires 33.

As described above, it is also possible to apply the combination of the through electrodes 32 and the metal wires 33 for electrically connecting the interposers 8, 13 and the semiconductor chips 9, 14 in the first and second modules 6 and 7. Also in a case where the through electrodes 32 are applied, it is preferable that the numbers of mounted semiconductor chips 9, 14 on the interposers 8, 13 are respectively set to 4 to 8. Similar to the first embodiment, by mounting only the modules 6, 7 whose electric characteristics are judged as acceptable on the wiring board 2, it is possible to improve a manufacturing yield of the stacked semiconductor package 31. Further, it is possible to realize a reduction in thickness, a reduction in manufacturing cost and the like of the stacked semiconductor package 31.

Also in the stacked semiconductor package 31 according to the third embodiment, it is preferable to set the ratio of the resin thickness T1 of the third sealing resin layer 20 to the resin thickness T2 of the sealing resin layers 11, 16 in the modules 6, 7 (T1/T2) to 1 or more (T1≧T2), similar to the first embodiment. The ratio of the elasticity modulus E1 of the third sealing resin layer 20 to the elasticity modulus E2 of the sealing resin layers 11, 16 (E1/E2) is preferably set to 1 or more (E1≧E2). Concrete values of the resin thicknesses T1, T2 and the elasticity moduli E1, E2 are also preferably set in a similar manner to the first embodiment. According to these structures, it is possible to suppress a warpage of the stacked semiconductor package 31.

### Fourth Embodiment

A stacked semiconductor package according to a fourth embodiment will be described with reference to FIG. 6. A semiconductor package 41 shown in FIG. 6 includes the same configuration as that of the stacked semiconductor package 21 according to the second embodiment, except that the through electrodes 32 are used to connect between the semiconductor chips 9 and between the semiconductor chips 14 in the first and second modules 22 and 7, and the uppermost semiconductor chips 9, 14 and the interposers 8, 13 are electrically connected by the metal wires 33, respectively, similar to the third embodiment.

As described above, it is also possible to apply the combination of the through electrodes 32 and the metal wires 33 for electrically connecting the interposer 8 and the semiconductor chips 9 in the module 22 to be FC-connected. Also in the stacked semiconductor package 41 shown in FIG. 6, it is possible to improve a manufacturing yield of the stacked semiconductor package 41, similar to the first to third embodiments. Further, it is possible to realize a reduction in thickness, a reduction in manufacturing cost and the like of the stacked semiconductor package 41.

Also in the stacked semiconductor package 41 according to the fourth embodiment, it is preferable to set the ratio of the resin thickness T1 of the third sealing resin layer 20 to the resin thickness T2 of the sealing resin layers 11, 16 in the modules 22, 7 (T1/T2) to 1 or more (T1≧T2), similar to the first embodiment. The ratio of the elasticity modulus E1 of the third sealing resin layer 20 to the elasticity modulus E2 of the sealing resin layers 11, 16 (E1/E2) is preferably set to 1 or more (E1≧E2). Concrete values of the resin thicknesses T1, T2 and the elasticity moduli E1, E2 are also preferably set in a similar manner to the first embodiment. According to these structures, it is possible to suppress a warpage of the stacked semiconductor package 41.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A stacked semiconductor package, comprising:
a wiring board having a first surface including external connection terminals and a second surface including internal connection terminals;
a first module, disposed on the second surface of the wiring board, including a first interposer, a plurality of first semiconductor chips mounted on the first interposer, first connecting members electrically connecting the first interposer and the first semiconductor chips, and a first sealing resin layer formed on the first interposer to seal the first semiconductor chips together with the first connecting members;
a second module, stacked on the first module, including a second interposer, a plurality of second semiconductor chips mounted on the second interposer, second connecting members electrically connecting the second interposer and the second semiconductor chips, and a second sealing resin layer formed on the second interposer to seal the second semiconductor chips together with the second connecting members;
third connecting members electrically connecting the first interposer and the internal connection terminals of the wiring board;
fourth connecting members electrically connecting the second interposer and the internal connection terminals of the wiring board; and
a third sealing resin layer formed on the second surface of the wiring board to seal the first and second modules together with the third and fourth connecting members.

2. The stacked semiconductor package according to claim 1,
wherein the third connecting member includes a metal wire, a printed wiring layer, or a metal bump, and
wherein the fourth connecting member includes a metal wire or a printed wiring layer.

3. The stacked semiconductor package according to claim 1,
wherein the first interposer has first connection terminals provided on a first surface on which the first semiconductor chips are mounted and second connection terminals provided on a second surface opposed to the first surface, the first connection terminals are electrically connected to the first semiconductor chips via the first connecting members, and the second connection terminals are electrically connected to the internal connection terminals of the wiring board via the third connecting members, and
wherein the second interposer has third connection terminals provided on a first surface on which the second semiconductor chips are mounted and fourth connection terminals provided on a second surface opposed to the first surface, the third connection terminals are electrically connected to the second semiconductor chips via the second connecting members, and the fourth connection terminals are electrically connected to the internal connection terminals of the wiring board via the fourth connecting members.

4. The stacked semiconductor package according to claim 3,
wherein each of the first and second interposers includes a silicon interposer or an interposer board.

5. The stacked semiconductor package according to claim 1,
wherein the third sealing resin layer satisfies a condition of T1≧T2, where T1 is a thickness of the third sealing resin layer on the second module, and T2 is a thickness of the first sealing resin layer on the first semiconductor chip and a thickness of the second sealing resin layer on the second semiconductor chip.

6. The stacked semiconductor package according to claim 5,
wherein each of the thickness T1 of the third sealing resin layer and the thickness T2 of the first and second sealing resin layers is in a range of 70 to 200 μm, and
wherein a ratio of the thickness T1 to the thickness T2 is in a range of 1 to 2.

7. The stacked semiconductor package according to claim 1,
wherein the third sealing resin layer satisfies a condition of E1≧E2, where E1 is an elasticity modulus of the third sealing resin layer, and E2 is an elasticity modulus of the first and second sealing resin layers.

8. The stacked semiconductor package according to claim 7,
wherein the elasticity modulus E2 is in a range of 22 GPa or more, and the elasticity modulus E1 is in a range of 25 to 30 GPa.

9. The stacked semiconductor package according to claim 3,
wherein the first sealing resin layer of the first module is adhered to the second surface of the wiring board via a first adhesive layer, and
wherein the second sealing resin layer of the second module is adhered to the second surface of the first interposer via a second adhesive layer while exposing the second connection terminals of the first interposer.

10. The stacked semiconductor package according to claim 9,
wherein the second connection terminals of the first interposer are electrically connected to the internal connection terminals of the wiring board via metal wires or printed wiring layers as the third connecting members, and
wherein the fourth connection terminals of the second interposer are electrically connected to the internal connection terminals of the wiring board via metal wires or printed wiring layers as the fourth connecting members.

11. The stacked semiconductor package according to claim 9,
wherein the first semiconductor chips are stacked in a stepped manner on the first surface of the first interposer, and electrically connected to the first connection terminals of the first interposer via metal wires or printed wiring layers as the first connecting members, and
wherein the second semiconductor chips are stacked in a stepped manner on the first surface of the second interposer, and electrically connected to the third connection terminals of the second interposer via metal wires or printed wiring layers as the second connecting members.

12. The stacked semiconductor package according to claim 9,
wherein first through electrodes are used to electrically connect between the first semiconductor chips, and an uppermost semiconductor chip in the first semiconductor chips stacked on the first interposer is electrically connected to the first connection terminals of the first interposer via metal wires or printed wiring layers as the first connecting members, and
wherein second through electrodes are used to electrically connect between the second semiconductor chips, and an uppermost semiconductor chip in the second semiconductor chips stacked on the second interposer is electrically connected to the third connection terminals of the second interposer via metal wires or printed wiring layers as the second connecting members.

13. The stacked semiconductor package according to claim 3,
wherein the second connection terminals of the first interposer are electrically and mechanically connected to the internal connection terminals of the wiring board via metal bumps as the third connecting members, and
wherein the second sealing resin layer of the second module is adhered to the first sealing resin layer of the first module via an adhesive layer.

14. The stacked semiconductor package according to claim 13,
wherein the fourth connection terminals of the second interposer are electrically connected to the internal connection terminals of the wiring board via metal wires or printed wiring layers as the fourth connecting members.

15. The stacked semiconductor package according to claim 13,
wherein the first semiconductor chips are stacked in a stepped manner on the first surface of the first interposer, and electrically connected to the first connection terminals of the first interposer via metal wires or printed wiring layers as the first connecting members, and
wherein the second semiconductor chips are stacked in a stepped manner on the first surface of the second interposer, and electrically connected to the third connection terminals of the second interposer via metal wires or printed wiring layers as the second connecting members.

16. The stacked semiconductor package according to claim 13,
wherein first through electrodes are used to electrically connect between the first semiconductor chips, and an uppermost semiconductor chip in the first semiconductor chips stacked on the first interposer is electrically connected to the first connection terminals of the first interposer via metal wires or printed wiring layers as the first connecting members, and
wherein second through electrodes are used to electrically connect between the second semiconductor chips, and an uppermost semiconductor chip in the second semiconductor chips stacked on the second interposer is electrically connected to the third connection terminals of the second interposer via metal wires or printed wiring layers as the second connecting members.

17. A method of manufacturing a stacked semiconductor package, comprising:
preparing a wiring board having a first surface including external connection terminals and a second surface including internal connection terminals;
disposing a first module on the second surface of the wiring board, the first module including a first interposer, a plurality of first semiconductor chips mounted on the first interposer, first connecting members electrically connecting the first interposer and the first semiconductor chips, and a first sealing resin layer formed on the first interposer to seal the first semiconductor chips together with the first connecting members;
stacking a second module on the first module, the second module including a second interposer, a plurality of second semiconductor chips mounted on the second interposer, second connecting members electrically connecting the second interposer and the second semiconductor chips, and a second sealing resin layer formed on the second interposer to seal the second semiconductor chips together with the second connecting members;
electrically connecting the first interposer and the internal connection terminals of the wiring board via third connecting members;
electrically connecting the second interposer and the internal connection terminals of the wiring board via fourth connecting members; and
forming a third sealing resin layer on the second surface of the wiring board to seal the first and second modules together with the third and fourth connecting members.

18. The manufacturing method according to claim 17,
wherein the first interposer has first connection terminals provided on a first surface on which the first semiconductor chips are mounted and second connection terminals provided on a second surface opposed to the first surface, the first connection terminals are electrically connected to the first semiconductor chips via the first connecting members, and the second connection terminals are electrically connected to the internal connection terminals of the wiring board via the third connecting members, and
wherein the second interposer has third connection terminals provided on a first surface on which the second semiconductor chips are mounted and fourth connection terminals provided on a second surface opposed to the first surface, the third connection terminals are electrically connected to the second semiconductor chips via the second connecting members, and the fourth connection terminals are electrically connected to the internal connection terminals of the wiring board via the fourth connecting members.

19. The manufacturing method according to claim 18,
wherein the first sealing resin layer of the first module is adhered to the second surface of the wiring board via a first adhesive layer,
wherein the second sealing resin layer of the second module is adhered to the second surface of the first interposer via a second adhesive layer while exposing the second connection terminals of the first interposer,
wherein the second connection terminals of the first interposer are electrically connected to the internal connection terminals of the wiring board via metal wires or printed wiring layers as the third connecting members, and
wherein the fourth connection terminals of the second interposer are electrically connected to the internal connection terminals of the wiring board via metal wires or printed wiring layers as the fourth connecting members.

20. The manufacturing method according to claim 18,
wherein the second connection terminals of the first interposer are electrically and mechanically connected to the internal connection terminals of the wiring board via metal bumps as the third connecting members,
wherein the second sealing resin layer of the second module is adhered to the first sealing resin layer of the first module via an adhesive layer, and
wherein the fourth connection terminals of the second interposer are electrically connected to the internal connection terminals of the wiring board via metal wires or printed wiring layers as the fourth connecting members.
